(19) United States
(12) Patent Application Publication
(10) Pub. No.: US 2018/0376614 A1
(43) Pub. Date: Dec. 27, 2018

(54) CHECK VALVE FAN COVER

(71) Applicant: Fortinet, Inc., Sunnyvale, CA (US)

(72) Inventors: Hua Keng Xiong, Burnaby (CA); Shenghua Jiang, Suzhou (CN); Qian Yu, Burnaby (CA)

(73) Assignee: Fortinet, Inc., Sunnyvale, CA (US)

(21) Appl. No.: 15/631,834

(22) Filed: Jun. 23, 2017

(51) Int. Cl. H05K 7/20

(52) U.S. Cl. CPC H05K 7/20145; H05K 7/20181; F04D 25/14; H05K 7/20172; H05K 7/20154

(57) ABSTRACT

A check valve cover to prevent backflow of air through a cooling fan. A circumferential base connects to a fan and flaps arranged in an annular pattern, the flaps each have an outer substantially fixed portion and an inner un-fixed portion. The flaps are flexibly fixed at the outer fixed portion to the circumferential base and are freely movable at the inner un-fixed portion. Flaps may have self-closing property and/or may incorporate one or more anti-vibration holes located between adjacent flaps. Check valve can be fitted on outlet side of a fan close to output side of the fan so that opening of the flaps towards fan is prevented to prevent backflow of air when the fan is not operational.

### COPYRIGHT NOTICE

Contained herein is material that is subject to copyright protection. The copyright owner has no objection to the facsimile reproduction of the patent disclosure by any person as it appears in the Patent and Trademark Office patent files or records, but otherwise reserves all rights to the copyright whatsoever.

### BACKGROUND

The present subject matter in general relates to check valves used for preventing back flow of air through a fan in an electrical system thereby allowing flow of air only in one direction.

Cooling fans are advantageous for long-term or continued operation of electronic systems/components without letting the enclosed components become heated up excessively after prolonged usage. The cooling fans keep the electronic components cool by continuously exhausting hot air thereby exhausting the generated heat. Any disruption in working of the cooling fans, therefore, would require shutting down of the device as it results in overheating of the internal components and might result in complete breakdown of the components of or the entire device.

However, disruption in working of a cooling fan cannot be totally avoided as the fan may fail or may need shutting down and/or removal for maintenance. For this reason, it is normal to provide more than one cooling fan to cater to such exigencies and ensure uninterrupted working of electronic devices. In such configurations, when one of the cooling fans is not functional the stopped fan itself can become an air inlet which affects cooling efficiency of the functioning fans. For this reason, use of a one-way check valve fan cover covering each of the fans is highly desirable. These fan covers/check valves can thus he installed to prevent backflow of the air at the time of fan failure or other non-operation.

There is room for improvements in known check valves especially in respect of the shape and orientations of check valve parts, the material for the check valve, the sound they generate due to the vibrations of flaps, ease of manufacturing, cost, and ease of installation and maintenance. There is therefore need in the art for an improved check valve for cooling fans.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplar language (e.g. “such as”) provided with respect to certain implementations herein is intended merely to better illuminate the developments hereof and does not pose a limitation on the scope of coverage otherwise claimed. No language in the specification should be construed as indicating any non-claimed element essential to the practice hereof.

Groupings of alternative elements or embodiments or implementations disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

### SUMMARY

The present disclosure relates to a cooling system for electrical and electronic devices. In particular, the present disclosure pertains to check valve fan cover (also referred to as check valve cover or simply as check valve or as fan cover or cover and all these terms used interchangeably hereinafter) for electrical and electronic devices that prevents backflow of air through a cooling fan in event of the fan being not in a functional state.

In an aspect, the disclosed check valve fan cover incorporates a circumferential base/frame/rim for connection to a fan and one or more flaps arranged in an annular pattern, wherein the flaps have an outer substantially fixed portion and an inner un-fixed or free portion. Each of the one or more flaps may be flexibly fixed at the outer fixed portion to the circumferential base and is freely movable at the inner free portion of the flap.

Various objects, features, aspects and advantages of the subject matter hereof will become more apparent from the following detailed description of preferred implementations, along with the accompanying drawing figures in Which like numerals represent like components.

### BRIEF DESCRIPTION OF THE DRAWINGS

The accompanying drawings are included to provide a further understanding of the present disclosure, and are incorporated in and constitute a part of this specification. The drawings illustrate exemplar implementations of the present disclosure and, together with the description, serve to explain the principles of the present disclosure.

In the figures, similar components and/or features may have the same reference label. Further, various components of the same type may be distinguished by following the reference label with a second label that distinguishes among the similar components. If only the first reference label is used in the specification, the description is applicable to any one of the similar components having the same first reference label irrespective of the second reference label.

FIGS. 1A and 1B illustrate exemplar isometric views of a fan mounted with a check valve cover hereof, with flaps of the check valve cover in closed and opened positions respectively in accordance with implementations hereof.

FIGS. 2A, 2B, and 2C illustrate different exemplar views of a check valve cover hereof showing different features in accordance with implementations hereof.

FIG. 3 illustrates an exemplar view of a check valve cover hereof with an alternate arrangement of flaps in accordance with implementations hereof.

FIGS. 4A and 4B illustrate exemplar isometric views of yet another alternative implementation of a check valve cover in opened and closed positions respectively in accordance with implementations hereof.

FIG. 5 illustrates an exemplar exploded view showing assembly of a check valve cover with a fan in accordance with implementations hereof.

FIG. 6 illustrates an exemplar view of a multi-fan assembly showing fitment of an airflow outlet plate for satisfactory functioning of a check valve cover hereof in accordance with implementations hereof.

FIG. 7 illustrates an exemplar method flow diagram for method of preventing backflow of air in a multi-fan assembly in accordance with implementations hereof.

### DETAILED DESCRIPTION

Devices and methods described herein relate to prevention of back flow of air in a cooling system when a fan of the cooling system is not operational or otherwise functioning. The following is a detailed description of implementations of the disclosure depicted in the accompanying drawings. The implementations are in such detail as to clearly communicate the disclosure. However, the amount of detail offered is not intended to limit the anticipated variations of implementations; on the contrary, the intention is to cover as understood by a skilled artisan all modifications, equivalents, and alternatives falling within the spirit and scope of the present disclosure as defined by the appended claims.

Each of the appended claims defines a separate invention, which for infringement purposes is recognized as including equivalents to the various elements or limitations specified in the claims. Depending on the context, all references herein to the “invention” may in sonic cases refer to one or more certain specific implementations only. In other cases it will be recognized that references to the “invention” will refer to subject matter broader than or as recited in one or more, but not necessarily all, of the claims. To the extent a term used in a claim is not defined below, it should be given the broadest definition persons in the pertinent art have given or would give that term as reflected in printed publications and issued patents at the time of filing.

Implementations described herein relate to a check valve fan cover to prevent air backflow in cooling systems such as modular cooling systems. In particular, the disclosed check valve cover and methods for making, installing and/or using the check valve cover can be applied in cooling systems for enclosed electrical and electronic devices so that cooling efficiency of the modular cooling system is not affected due to air backflow when any particular fan is not operational.

The disclosed check valve fan cover can allow air to flow in one direction but substantially blocks flow of air in other direction, and can be installed on the outlet side of a fan of a cooling system such that airflow from the fan to outside is permitted, but airflow from outside towards and/or through the fan to the inside of the device is blocked thus preventing backflow of air toward the enclosed electrical or electronic devices when the fan is not operational.

In an aspect, the functionality of allowing air to flow in one direction but blocking its flow in the other direction is achieved in the disclosed check valve fan cover by one or more flaps or blades or fins arranged in a predefined pattern, wherein, the flaps are constrained to open only in one pre-selected direction, the pre-selected direction being the direction of flow of air being exhausted by a fan thereby allowing the exhausted air to flow outwardly. The flaps are restrained from opening or otherwise moving in the opposite direction to maintain the flow blocking position and prevent back flow of air in the opposite direction when the fan is not operational.

In an aspect, a check valve cover hereof for blocking backflow of air through a non-operating fan has a circumferential base for connection to a fan and one or more flaps arranged in a substantially annular pattern, the annular pattern having an outer substantially fixed portion and an inner un-fixed or free portion; the of flaps each being flexibly fixed at the outer fixed portion to the circumferential base and being freely movable at the inner un-fixed portion of the pattern.

In another aspect, each of the flaps is disposed flexibly fixed at their respective outer annular edges to the circumferential base and pointing from there inwardly toward the central hub area of the fan. The internal un-fixed or free portion of each flap is thus disposed to rest adjacent the hub and/or static central part of the fan when the flaps are not flexed outwardly away from the hub.

In an aspect, the one or more flaps may have a self-closing or resilient property wherein they deflect under force of airflow to provide an outward opening for air to flow but return to closed position when airflow is not there, or might otherwise be moving/flowing or attempting to flow in the un-desired back flow direction. The self-closing property of the flaps may be due to an inherent property of the material chosen therefor. This may be an inherent resilient property or otherwise. In an aspect, closing of the flaps without help of gravitational force may help the disclosed check valve cover to be used in any orientation.

In another aspect, the one or more flaps may be patterned on the check valve cover by slits with one side of each of the flaps remaining attached to the check valve cover.

In an aspect, the one or more flaps or fins are formed on single piece check valve cover by slits such that the flaps remain attached to the remaining part of the check valve cover (the remaining part referred to as the circumferential base or frame) along one side—fixed side as this side does not move away from the check valve cover and keeps the flaps attached to the circumferential base/frame of the check valve cover. The flaps are adapted or configured to bend relative to the circumferential base/frame along the respective fixed sides to move between a closed position and an open position.

In an aspect, the fixed side may incorporate one or more substantially transversely positioned slots for easy bending of the flaps along the fixed sides.

In an aspect, the disclosed check valve cover may incorporate one or more anti-vibration vent holes or reduced areas allowing for flow therethrough. The vent holes may be typically located between adjacent flaps/fins, though are not limited to one such vent hole between two adjacent flaps. The anti-vibration vent holes may provide a small passage to allow a small amount of airflow to pass through when the check valve fan cover is in blocking or closed state thus preventing frequent opening and closing of flaps. As mentioned, the anti-vibration vent holes may also be disposed to prevent or reduce noise, which can get generated due to vibration of the flaps.

In an aspect, the disclosed check valve cover is a single piece/unitary molded part. In some such implementations, one or more flaps may be patterned in a specified manner by suitably positioned slits defined between flaps. In an exemplar implementation, the molded single piece check valve cover can be configured for fitment on an outlet side of a fan such that the flaps are restrained from deflection too far inwardly toward the fan by the fan hub or by static airflow guide blades of the fan or by a finger guard of the fan but are free to open outwardly toward the outer side at the start of flow of air from the fan. With this configuration in place, the backflow of the air is prevented when the associated fan is not operational.

In an exemplar implementation, one or more flaps are arranged in check valve cover hereof such that they substantially cover the annular space between outer diameter of a fan (or outer diameter of fan blades) and the fan hub (with exception in some instances the slots and/or the air vent holes, if used). In an exemplar implementation, the flaps can be generally of trapezoidal shape with unequal parallel sides. The larger of the two parallel sides of the trapezoidal shape can be the one fixed to the circumferential base or frame of the check valve cover and work in some implementations as a hinge or the like allowing flap like movement of the flap relative to the base. The larger of the two parallel sides may be thus positioned along or near outer periphery of the fan, and smaller of the two parallel sides can be positioned adjacent or near to the central portion or the hub of the fan. The smaller of the two parallel sides is or defines the free end of the flap that is configured to move outward when subject to proper outward airflow and rests adjacent the fan hub or static fan blades of the fan when there is no operation of the fan or when in position to block an attempted back flow condition. In some implementations, the inner, smaller parallel side of the otherwise trapezoidal shape can be curved to match outer diameter of the hub, though will in many implementations rest in the non-operational fan state inside the outer diameter of the hub. Thus the trapezoidal shaped flaps attached to base or frame of the check valve cover and positioned next to each other can define a regular or irregular convex polygon or an approximate thereof, having in some instances a number of sides equal to number of flaps, though other implementations may include more or less sides relative to flaps. In some further alternatives, a hole or aperture can be defined or disposed in or about the relative center and may match the hub of the fan. The circumferential base/frame of the check valve cover can in many implementations be square shaped matching a size and/or shape of an individual fan.

In another aspect, the present disclosure relates to and may be usable in or with a multi-fan assembly as well. In a multi-fan assembly, equal numbers of check valve fan covers can be used as the number of fans assembled in the multi-fan assembly, wherein a single check valve cover is provided for each fan unit. In the multi-fan assembly arrangement, an airflow outlet plate can be mounted such that an opening gap allowing space for flaps of each check valve cover to open is available.

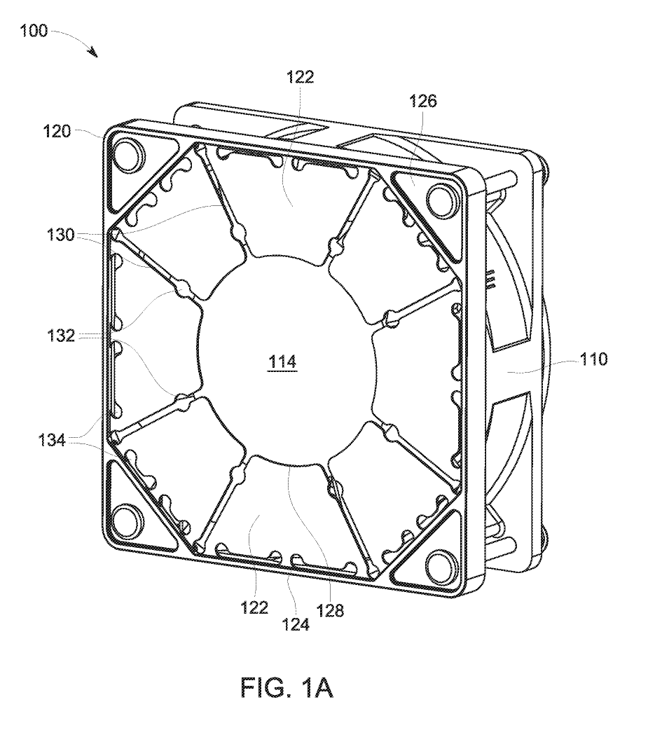

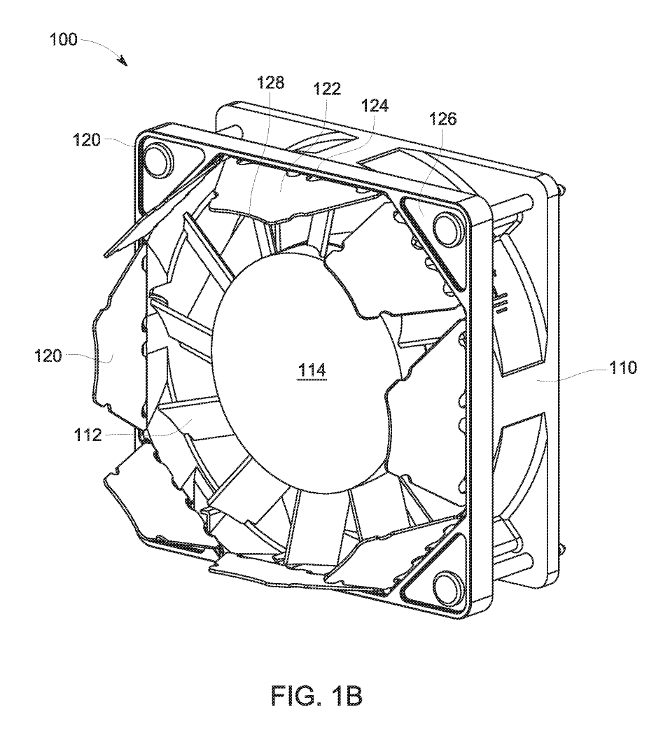

FIGS. 1A and 1B illustrate exemplar isometric views of a fan assembly 100 mounted with a check valve cover 120 hereof on a fan 110, with flaps 122 of the check valve cover in closed and opened positions respectively in accordance with one or more implementations hereof. As shown, the disclosed check valve cover 120 can be mounted directly on a fan 110 to prevent backflow of air through the fan 110 when the fan 110 is not operating or operational. As shown, the check valve cover 120 can incorporate one or more flaps such as flap 122 and a. circumferential base 126. The flaps 122 can move or pivot or otherwise rotationally advance or re-position between a closed disposition shown in FIG. 1A and an open disposition as shown in FIG. 1B. Opening of the flaps 122 provides passage for air to pass through the check valve cover 120 whereas when the flaps 122 are closed the passage is closed and flow of air is blocked.

As can be seen from FIGS. 1A and 1B, flaps 122 have a fixed side 124 thereof attached to the circumferential base 126 and a free side 128. The connection between or at fixed side 124 and the circumferential base 126 is such that it is about this connection that each respective flap turns/bends during movement between open position and closed position and vice versa. The fixed sides 124 may thus be disposed to function like a hinge or the like to enable movement of the flaps 122 between the two positions. In an aspect, an inherent property as for example a resilience of the chosen material of the check valve cover 120, which is also the material for the side 124, may provide the self-closing property to the flaps 122 wherein the side 124 of the flaps 122 allows for both the outward bending motion and in some instances may be disposed to resiliently tend to keep or return them in or to the closed position; i.e., upon removal of the force of the air tending to open the flap, the resilient characteristic can move the flap back to a closed position.

In an aspect, movements of flaps 122 from the closed position of FIG. 1A to the opened position of FIG. 1B can take place under force of air being exhausted by fan 110; i.e., as fan 110 operates normally to expel air, the generated airflow will open the flaps 122. However, the resilient or self-closing property can be disposed to cause the flaps 122 to return back to the closed position by themselves when there is no air being exhausted by fan 110, and consequently when there is no force to keep the flaps 122 in opened position.

In an aspect, the check valve cover 120 can be positioned adjacent to fan 110 so that flaps 122 are prevented from opening inwards i.e. towards the fan 110 by static airflow guide blades 112 (FIG. 1B) and/or by hub 114 of the fan 110. Therefore, the flaps 122 cannot be undesirably opened inwardly by an inward flow of air i.e. backflow that may arise when the fan 110 is not in operation. Thus, the check valve cover 120 allows unhindered flow of air exhausted by the fan 110 but prevents backflow of air when the fan 110 is not in operation.

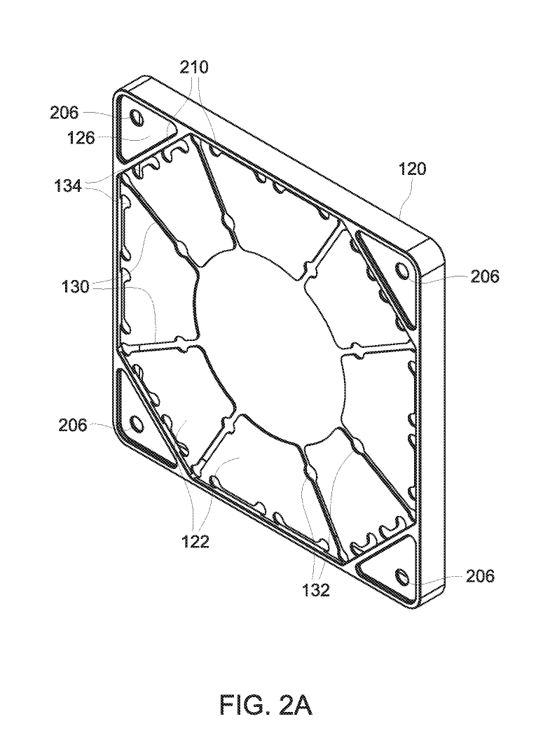

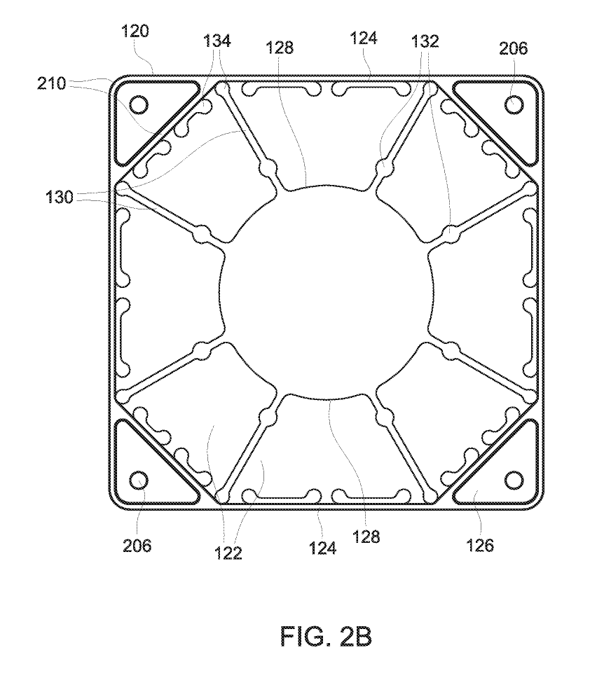

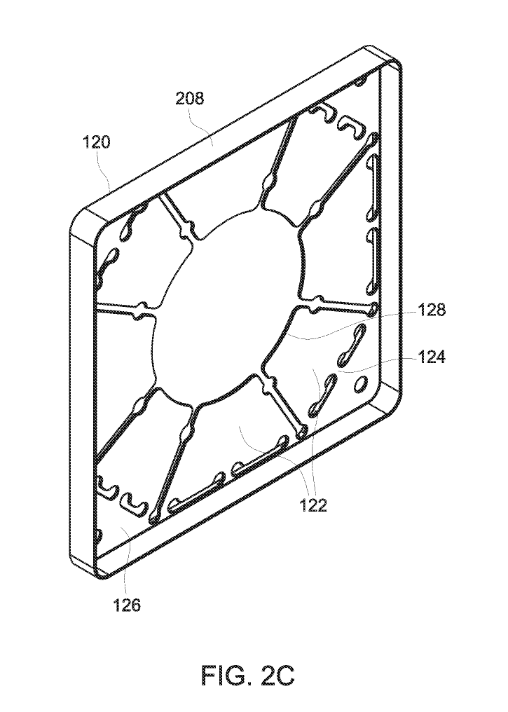

In an aspect, the one or more flaps/fins may be patterned on and/or as integral parts of a single or unitary piece check valve cover 120 by slits such that the flaps 122 remain attached to the remaining part of the check valve cover (the remaining pail referred to as the circumferential base or frame 126) along one side; namely, fixed side 124, as this side does not move away from the check valve cover 120 and keeps the flaps 122 attached to circumferential base/frame 126 of the check valve cover 120. In an implementation, the slits may be radially disposed to form radial sides such as sides 130 (see e.g., FIG. 2B) of the flaps 122.

In an aspect, the fixed side 124 of flaps 122 may incorporate one or more transversely positioned slots such as slots 134 for ease of bending of the flaps 122 along the fixed sides 124 so that resistance to opening by exhausted air is minimal and the check valve is sensitive to even low airflows. Also, the flaps 122 may in some implementations be more readily configured with such slots 134 or the like so that the remaining portion of material of the fixed side 124 provides enough and/or appropriate restoration force for the flaps 122 to return back to closed position on their own when flow of exhaust air is stopped.

The disclosed check valve fan cover 120 may further incorporate one or more anti-vibration vent holes or apertures such as holes 132 that are here shown located between adjacent flaps 122 (here shown one aperture 132 between two adjacent flaps 122) such that each of two adjacent flaps 122 carries a half of the aperture, here shown as each having a relatively semi-circular hole on its radial side 130 as shown in FIGS. 1A, 1B, 2A, 2B and 2C. In an aspect, the anti-vibration vent apertures 132 may be disposed to prevent frequent opening and closing of flaps 122 that may occur as air may try to pass through the slit 130 between the flaps 122. The anti-vibration vent apertures 132 located between the two flaps 122 can stabilize the flaps 122 by allowing passage of small amount of air through them and thereby, prevent the vibrations that might be caused due to unsteady airflow when the complete fan outlet is blocked. In an aspect, prevention of vibration also prevents noise that can be generated due to vibration of the flaps 122. Inconsistent airflow can thus be mitigated against, reducing undesired movement of the flaps and reducing noise.

FIGS. 2A, 2B and 2C illustrate different exemplar views of a check valve cover 120 showing different possible though non-limiting features in accordance with some implementations hereof. As shown, the check valve cover 120 can be of single piece or unitary construction incorporating a circumferential base 126 and one or more flaps 122, and can be made by a molding process using material that can provide a self-closing or resilient property to the flaps 122. Such a material could be any or a combination of materials selected from but not limited to silicon rubber, polyurethane, polyethylene and polyester. In a preferred implementation, silicon rubber may be used for the single piece check valve cover 120 as silicon rubber does not lose its mechanical properties even after prolonged use at elevated temperatures of for example up to about 120 degrees C. Therefore, a check valve cover 120 made of silicon rubber would likely retain its opening and self-closing properties without any relative deterioration.

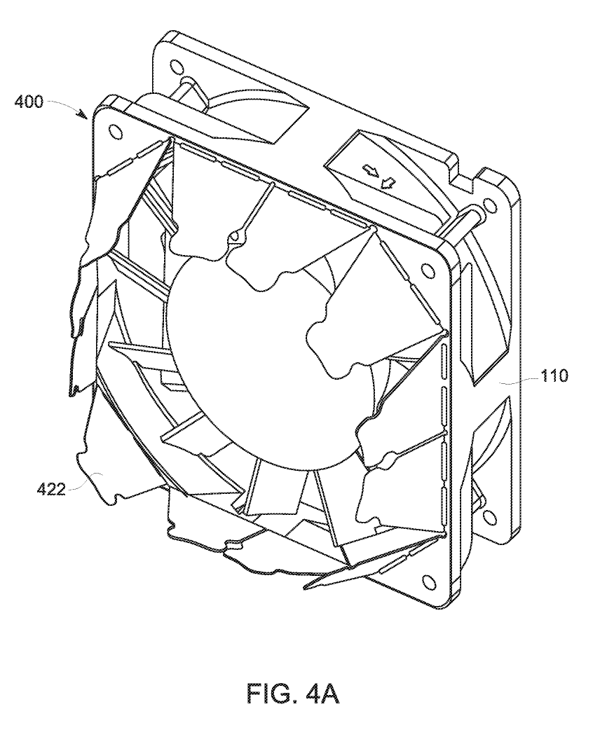

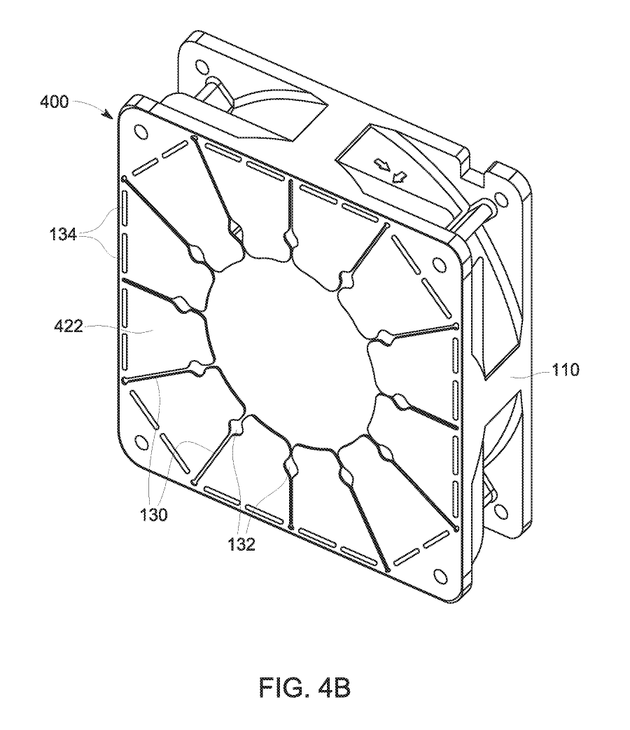

In an aspect, flaps 122 in the molded check valve cover 120 can have a thin film like cross section (as described in and/or relative to FIGS. 4A and 4B, below). Alternatively, they can be of variable thickness such that the flaps 122 may be thicker towards their fixed side 124 as compared to the opposite free side 128, i.e. the thickness of the flaps 122 may be appreciated in some implementations as reducing from the fixed side 124 to the free side 128 that is opposite to the fixed side 124. In an exemplar implementation the flaps 122 can have a thickness of 1.0 mm at the inner tip, i.e. the free end 128, and 1.3 mm at the root i.e. at or near the fixed side 124. In an aspect, reducing thickness may reduce weight of the flaps 122 making it that much easier to open under airflow thereby making them responsive to even low expulsion airflows.

In an exemplar implementation, a molded single piece check valve cover 120, being configured for fitment on outlet side of a fan, can be of a shape and size to match a desired fan frame; as here shown, a relatively square-type shape as shown in accompanying figures, and of size matching frame of the fan. Other sizes and shapes can be made to be accounted for and fit by relative covers 120 according hereto as well. The cover 120 hereof may incorporate corresponding holes for attachment to a fan, as shown here, there are four holes one each for each of the respective corners such as holes 206 positioned at the four comers. The check valve cover 120 can also incorporate a depending skirt 208 around its periphery projecting inward toward the side facing the fan, wherein the skirt 208 can engage with/wrap around the outer periphery of the fan on Which the check valve cover 120 is fitted, and helps to retain the check valve cover 120 in position. The skirt can he disposed to reduce or allow little or no air to leak from the gap between fan housing and check valve cover 120. Because of the 3D skirt shape, in some implementations, no adhesive tape may be needed to bind the check valve to fan housing. This can be advantageous in many fans where fan housing does not have enough area for connecting the check valve by adhering the check valve thereto.

In an exemplar implementation, the check valve cover 120 can further incorporate raised ribs such as ribs 210 on its outer face wherein the ribs 210 can be positioned around holes 206 and along the side edges of the check valve cover 120 so as to strengthen circumferential base 126 of the check valve cover 120. The multiple ribs may he disposed to increase fan check valve structural strength and stability. Hence, at the fan check valve frame edges and area around mounting holes, more silicon rubber material may thus be disposed to keep the fan check valve rim/circumferential base 126 in a relative flat shape even when check valve flap is pivoted up into the open position.

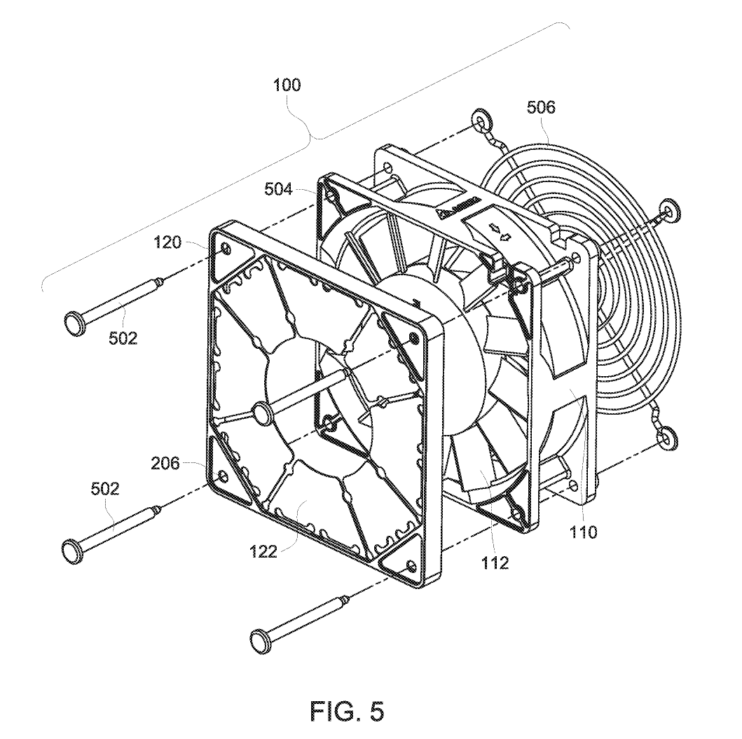

In an aspect, skirt 208 and ribs 210 may provide rigidity to circumferential base or rim or frame 126 of the check valve cover 120 so that the disclosed check valve cover 120 can be fitted on a fan with help of pins (see pins 502 in FIG. 5, described below) through the four holes 206 without need of any adhesives along sides in some implementations. Thickness of the frame 126, depth of the skirt 208 and height of the ribs 210 can be adapted or configured to be adequate to meet the preference.

In an exemplar implementation, flaps 122 may be arranged in a check valve cover 120 such that they cover a substantial portion of the annular space or distance between the outer diameter of a fan and the fan hub 114 (see FIGS. 1A and 1B). In an exemplar implementation and as shown in FIG. 2A, 2B, and 2C the flaps 122 can be generally of a sort of trapezoidal shape with unequal parallel sides. The larger of the two parallel sides can be the fixed side 124 that may be disposed to work as or like a hinge as described hereinabove. The fixed side 124 can be positioned along an outer periphery or circumference of the fan, and the smaller of the two parallel sides can be the free side 128 and positioned adjacent the huh 114 of the fan 110. The smaller of the two parallel sides i.e. the free side 128 can be straight or may be curved to match or be similar to the outer diameter of the hub 114. Thus, the somewhat trapezoidal shaped flaps 122 positioned next to each other can define a regular or irregular convex polygon at the circumference, the flaps positioned within the check valve cover 120 with an aperture in the center that may be associated with the size and/or shape of the hub 114 of the fan 110. An aperture in the middle can be effective to remove unnecessary flap material and thus weight for the flaps 122 to be lighter and thus more responsive to movement of air exhausted through and by the fan. It is to be appreciated that there can be many ways of arranging the flaps 122 within the check valve cover 120, and all such variations are well within the scope of the present disclosure.

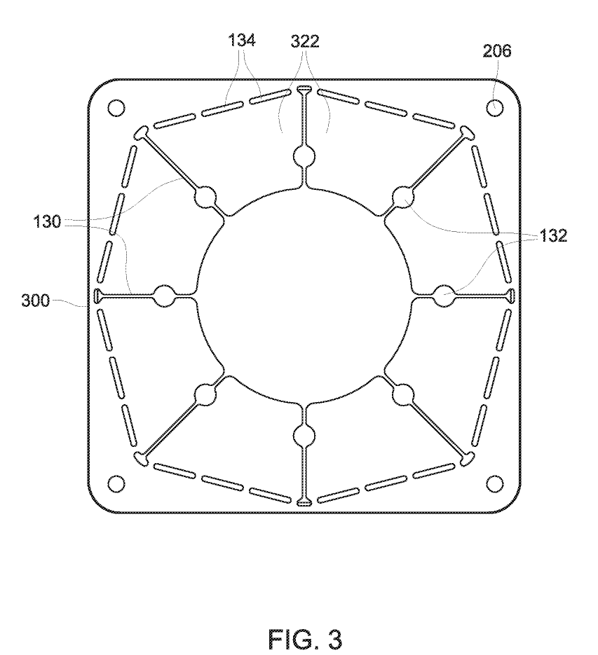

FIG. 3 illustrates an alternative or different configuration of flaps 322 for a check valve cover 300. While the exemplar configurations of respective FIGS. 2B and 3 each have eight flaps arranged in a substantially octagonal manner, their arrangement is different in that while in FIG. 2B (and see FIG. 1A, e.g.) all eight apex points of the flaps 122 of the octagon thereof are located along sides of the square shaped check valve cover 120 of FIG. 2B, rather, in the check valve cover 300 of FIG. 3 four apexes of the corresponding flaps 322. are at mid-point of the sides and the other four apexes are near to the four corners making the flaps 322 of the check valve cover 300 of more similar sizes relative to each other. Thus the flaps 322 of check valve cover 300 are also of more similar weights to each other, as well as of similar dispositions relative to the fan and fan housing such that they will be impacted by more similar sized quantities of airflow; these flaps 322 thus all being more similarly responsive and perhaps thus also more efficiently effective in operation. For these reasons, the check valve cover 300 of FIG. 3 may be more suited for small fans. Other features may remain same for both the configurations.

FIGS. 4A and 4B illustrate exemplar isometric views of yet another alternative implementation of a check valve cover 400 in opened and closed positions respectively in accordance with implementations hereof. The check valve cover 400 of FIGS. 4A and 4B incorporates a larger number of flaps 422. As can be seen it has twelve flaps 422 as compared to eight flaps 122 in check valve cover 120 or flaps 322 in check valve cover 300. Check valve cover 400 having a larger number of flaps 422 may be seen as having the flaps be more similarly sized like that in FIG. 3, and/or may also or alternatively be more suitable for larger fans as a larger area may have need to be covered by the flaps. Keeping the number of flaps same on larger fans would make the flaps perhaps unduly heavy and therefore sluggish in their movement between closed and open positions and vice-versa. However, increasing the number of flaps in proportion to area of the fan may not be viable beyond a point as diminishing returns may set in. Under such circumstances, the weight of the flaps can/might be reduced by following a thin film configuration for the flaps wherein the thickness of flaps is reduced by comparison and such would help to keep their weight low in lieu of the tapering configuration as disclosed relative to FIGS. 2A, 2B and 2C. I.e., a different material, e.g., a thin film material might be used for an implementation such as this (though would likewise be usable in/with other implementations perhaps as well).

A note on alternative shapes and sizes and materials of and/or selected for flaps may include acknowledgement that the airflow from any respective fan may in some circumstances by greater or less than other fans. Thus, the materials, weights, sizes and/or shapes of respective flaps may be more or less of concern in discrete implementations. The level of material resilience may also be of concern. In some implementations, a thin film may be acceptable or preferred (see e.g., but not limited to implementations such as shown in FIGS. 4A and 4B). Note, material costs and mere adhesive uses for installation may present desirable design influence for a thin film choice. Thin films however may not provide a higher degree of robustness against possible failure or reliability in resilient re-closure in higher flow or other fan choices. Thus, a molded plastic option, as introduced above might prove more desirable with such alternative fans. Moreover, the shapes referred to may play a part, as in the option of thicker flap dimensions nearer the fixed hinge area 124, versus a possible thinner flap dimension nearer the inner free end 128. Corresponding weights and material properties, e.g., resilience can thus be accounted for relative to the normal fan operation, fan speed and flow rate and volume of airflow therethrough. Slots 134 can be made larger or smaller to assist in accounting for level of resilience and resistance to airflow, as can the sizes and/or existence of apertures 132. A further possible impact on size/shape and related flap choice can involve the relation of any one or more flaps to the geometry of the cover in this, it may be that a square cover may present an opportunity for different fan coverage at the corners versus the sides; i.e., polygonal circumferential base shape will be inexact in attempted matching of the otherwise typical circular fan outlet. In this, then, it can be seen that the side flaps of the implementations of FIGS. 1A and 2B, inter alia, which are larger/wider than the corner flaps, are thus likely to be impacted by a different amount of the overall fan exhaust airflow. In FIGS. 1A and 2B, it appears these side flaps will catch more of the flow than the corner flaps. In this then, it may be desirable to manipulate the relative weights, sizes and/or shapes to achieve more uniform flow through the totality of the flaps. Compare the double side flap options of FIGS. 4A and 4B which thus provide more similarly sized flaps in width; however, to make this change, the relative lengths of the flaps of FIGS. 4A and 4B are more distinct, the corner flaps being longer; thus, the operation of the corner flaps may here need/want some assist in ensuring similar reaction to airflow from the fan. Note, the FIG. 4A/4B alternative may highlight the greater impact of the corner connection as involving some reduced air impact area on the corner flaps—the sides/comers of the fixed portions are attached to the fan corners and thus, a portion of the corner flaps is blocked from the airflow of the circular fan channel this may affect desired operability of the flaps under normal fan use. Material size and/or shape can be manipulated to reduce possible negative affect. Lastly here, the FIG. 3 implementation can mitigate against possible different reactivity of corner flaps by establishing a more uniform distribution of shapes around the annular pattern of flaps. In FIG. 3, no corner only flaps occur and all flaps are at least partly disposed at the corners thus, a more uniform operation of all flaps may occur.

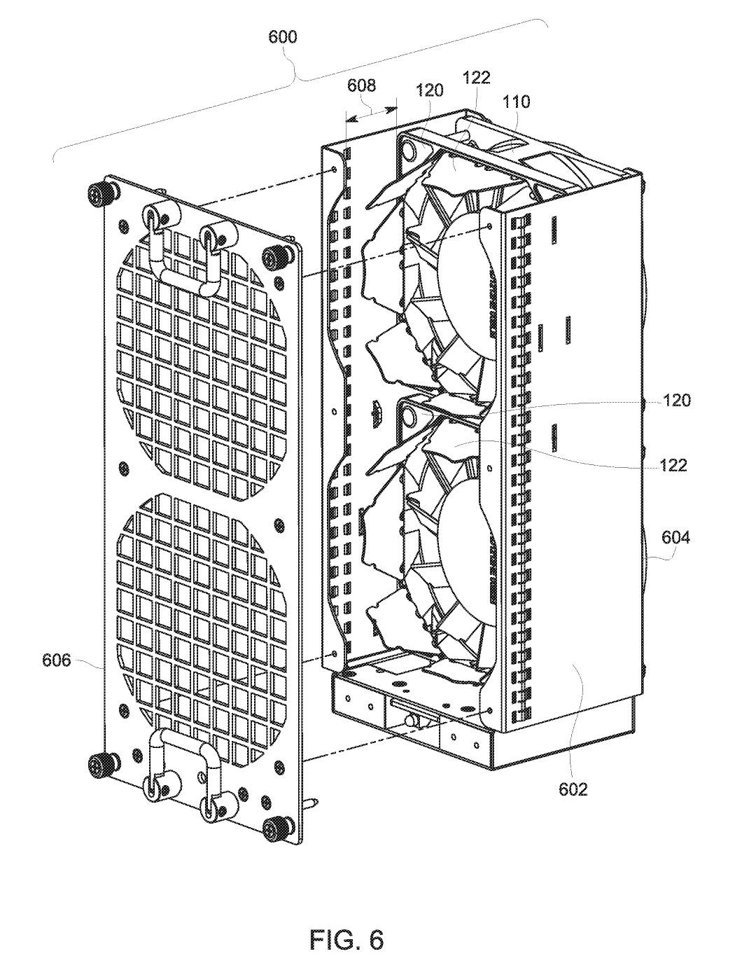

In another implementation, the developments hereof may relate to methods of manufacture and/or use. In a particular example, a method of attaching a check valve cover 120 to a fan 110 in an assembly 100 and/or to a multi-fan assembly 600 is shown and described. In an aspect, each fan 110 whether separately or as may he disposed in and/or associated with and as part, of a multi-fan assembly 600 (refer to FIG. 6) can be fitted with an independent check valve cover 120. A method of attaching the check valve cover 120 to a fan has been illustrated in FIG. 5. In an aspect, the disclosed check valve cover 120 is installed on the outlet side of the fan 110, and as described earlier and shown in FIGS. 2A, 2B and 3, inter alia, the check valve cover 120 can include mounting holes, such as four holes 206, on its four corners for the purpose of fitment of the check valve cover 120 to the fan assembly 110. The fitment may be facilitated as shown in FIG. 5 by using pins or screws or bolts 502 that can be inserted through the mounting holes 206 in the check valve cover 120 and travel through a set of matching holes 504 in pre-defined positions on the fan 110. Further, the pins 502 after passing through the fan 110 can be finally locked with or through corresponding holes in a fan finger guard 506 at the other side i.e. inlet side of the fan 110. Steel or other metal or robust materials may be used for the pins 502. In many implementations, no adhesive is required at the four edges of the check valve cover 120 to further support the fitment of the check valve cover 120 to the fan 110 besides use of the pins 502. In some implementations, as for example where thin film material is used; adhesives may be used in lieu of bolts/pins 502. Further, as mentioned above the cover flaps may be disposed to rest against static airflow guide blades 112 and/or the hub 114 of the fan 110 so that further inward movement or opening of flaps 122 is prevented by the guide blades 112 and/or the hub 114 to prevent backflow of air from the outlet side.

In an aspect, installation of a disclosed check valve cover 120/300/400 on a respective fan 110 would preferably include disposition of enough space on the outlet side of the fans 110 for the flaps 122/322/422 to sufficiently open towards exhaust/outlet side. For this, as shown for one non-limiting example in FIG. 6, airflow outlet plate 606 can be disposed to be mounted on fan mounting enclosure 602 of multi-fan assembly 604 at an adequate distance, such as shown by distance 608 in FIG. 6, for the flaps 122/322/422 to open appropriately or fully. Similar dispositions may be configured for fan and cover assemblies 100/500 or the like in other overall electrical frame structures (not shown) as well.

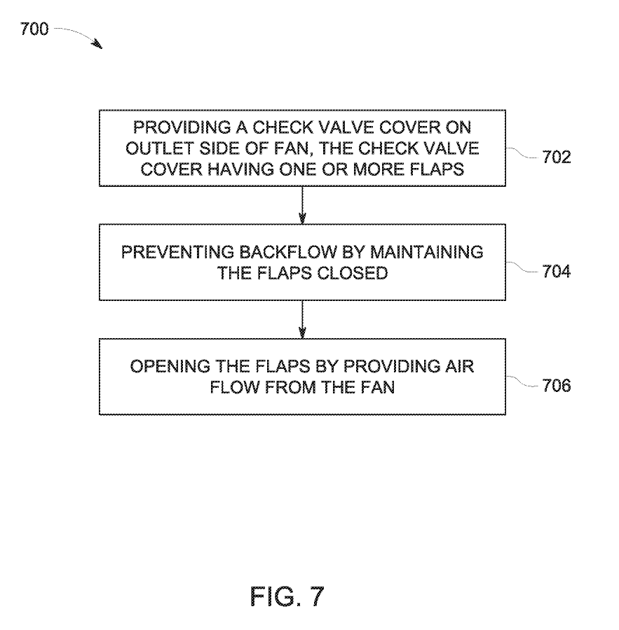

FIG. 7 illustrates an exemplar method flow diagram 700 for a method of use hereof. The method 700 may generally for alternately preventing backflow and allowing normal fan directed flow of air in a single fan 110 or in a multi-fan assembly such as fan assembly 600 (see FIG. 6). Step 702 of the method can be to provide a check valve cover on the outlet side of a fan. In a multi-fan assembly, preferably a cover for each fan therein would be provided such that there is one check valve cover for each fan in the multi-fan assembly. As described hereinabove, each check valve cover of the disclosed method may be a check valve cover 120 hereof or the like that comprises a circumferential base for connection to the respective fan and one or more flaps arranged in an annular pattern, the annular pattern covers the annular area defined between the hub of the fan and the outer diameter of the fan. Further as also described, the flaps may have an outer substantially fixed portion disposed close to the outer diameter of the respective fan, and an inner un-fixed portion disposed close to the hub of the respective fan. Each of the flaps is flexibly fixed at the outer fixed portion of the flap to the circumferential base of the cover and is freely movable at the inner un-fixed portion of the respective flap.

Step 704 of the disclosed method can be preventing backflow by preventing opening of the flaps. The preventing of opening may include preventing inward movement of the one or more flaps towards the fan when the fan is subject to possible backflow of air when the corresponding fan is not in operation. This prevention can be achieved by configuring or adapting or mounting the check valve cover adjacent to the output side of the respective fan so that the flaps are blocked from inward movement by the hub and/or the static blades of the fan. Fitting the check valve cover close to or touching static airflow guide blades and/or the hub of the respective fan prevents opening of the flaps inwardly toward the interior of the respective fan and thus under backflow conditions, which may arise when the respective fan is not operating or operational. In such position, the flaps will not open and thus will not allow backflow to take place.

Step 706 of the disclosed method can be directed to the rather normal operation of the fan exhausting air in a normal outward flow pattern. As such, this operation allows for the flaps to move outwardly under pressure of the fan-blown air; i.e. to allow the one or more flaps to open outward from the outlet side under influence of airflow being exhausted by the corresponding fan. In some implementations, the outward flap movement may be assisted by the provision adequate space on outlet side of the one or more check valve covers as shown for example relative to the implementation of FIG. 6. The adequate space on outlet side of the one or more check valve covers can be provided by maintaining a suitable gap between the one or more check valve covers and airflow outlet plate of the multi-fan assembly.

In an aspect, the flaps of the check valve cover hereof may also have an auto-closing property, as for example, resilience, wherein the one or more flaps open out under force of airflow but close or move to the closed position by themselves when the airflow is stopped.

In an aspect, the disclosed check valve fan cover incorporates a circumferential base/frame/rim for connection to a fan and one or more flaps arranged in an annular pattern, wherein the flaps have an outer substantially fixed portion and an inner un-fixed or free portion. Each of the flaps is flexibly fixed at the outer fixed portion to the circumferential base and is freely movable at the inner free portion of the flap.

In an aspect, the annular pattern of the one or more flaps covers an annular area between an outer diameter of fan blades and the hub of the fan by disposing the outer substantially fixed portion of the flaps close to the outer diameter of the fans, and the inner un-fixed portion close to the hub of the fan. Each of the flaps is flexibly fixed at the outer fixed portion to the circumferential base and freely movable at the inner un-fixed portion of the flap.

In an aspect, the one or more flaps may be patterned on the check valve cover by slits with one side of each of the flaps remaining attached to the circumferential base.

In another aspect, the one or more flaps may have thin film cross section or a cross section with tapering thickness such that they are thicker on the outer substantially fixed portion and thinner on the inner un-fixed portion.

In an aspect, each of the flaps may be of a generally trapezoidal shape with unequal parallel sides. The larger of the two parallel sides can form the outer substantially fixed portion, and smaller of the two parallel sides can form the inner un-fixed portion. Further, the smaller of the two parallel sides may be curved to match outer diameter of hub of the fan.

In an aspect, the trapezoidal shaped flaps may be positioned next to each other to define a regular or irregular convex polygon. The larger of the two parallel sides of the trapezoidal shaped flaps can define sides of the polygon, and the curved smaller of the two parallel sides can define a hole or aperture in the center that matches the hub of the fan. The polygon with the aperture in the center thus formed can cover the annular space between outer diameter of fan blades and hub of the fan.

In an aspect, the flaps have self-closing or resilient property, such that they open out under force of fan-forced airflow but close by themselves when the airflow is stopped.

In an aspect, the check valve cover may incorporate transverse slots along the outer substantially fixed portion that keeps the respective flaps attached to the circumferential base of the check valve cover.

In an aspect, the check valve cover incorporates one or more anti-vibration holes, wherein the anti-vibration holes may be located between adjacent flaps to allow passage of small amount of air through the check valve cover to prevent vibrations in the flaps.

In an aspect, the check valve cover is configured for direct fitment on output side of the fan and is of square shape matching shape of frame of the fan. The polygon with a hole in center defined by the trapezoidal shaped flaps can lie within the square shaped check valve cover.

In an aspect, the square shaped check valve cover further incorporates a depending skirt around the periphery projecting toward the side facing the fan. The skirt wraps around outer periphery of the fan when the check valve cover is fitted on the fan.

In an aspect, the square shaped check valve cover further incorporates holes at four corners. The holes may match similar holes in the fan and facilitate fitment of the check valve cover on the fan using pins/bolts or like elongated connection members.

In an aspect, the check valve cover further incorporates raised ribs on outer face. The raised ribs may be positioned around the four holes and side edges of the check valve cover to strengthen the check valve cover.

In an aspect, the check valve cover is made of silicon rubber, and manufactured by molding process.

In another aspect, the present disclosure relates to multi-fan assembly as well. In a multi-fan assembly, equal numbers of check valve fan covers can he used as the number of fans assembled in the assembly, wherein, a single check valve cover is used with each fan unit. In the multi-fan assembly arrangement, airflow outlet plate can be mounted such that an opening gap allowing space for flaps of the check valve cover to open is available.

In another aspect, the disclosure also provides a method for preventing backflow of air through a nonfunctional fan in a fan assembly, the method comprising steps of (a) providing a check valve cover on the outlet side of the fan; (b) preventing backflow by the one or more flaps blocking the flow of air into the fan when the corresponding fan is not in operation; (c) alternately opening the one or more flaps outwardly under influence of airflow being exhausted by the corresponding fan.

In an aspect, the check valve cover of the method may comprise a circumferential base for connection to the fan and one or more flaps arranged in an annular pattern. The one or more flaps may cover the annular area between the outer diameter of the fan and hub of the fan. The flaps may have an outer substantially fixed portion disposed close to the outer diameter of blades of the fan, and an inner un-fixed portion disposed close to the hub of the fan. Each of the flaps may be flexibly fixed at the outer fixed portion to the circumferential base and freely movable at the inner un-fixed portion of the pattern.

In an aspect, the flaps of the disclosed method may have one or both an auto-closing or resilient property, wherein the flaps open out under force of fan-forced airflow but close by themselves when the airflow is stopped.

In an aspect, adequate space on outlet side of the check valve cover may be provided by maintaining a suitable gap between the check valve cover and airflow outlet plate of the fan assembly.

As per the disclosure herein, the said check valve cover possesses a simple pattern and therefore does not require any special manufacturing method and can therefore be manufactured using any conventional methods. Therefore, the check valve cover can be mass produced with attended cost advantage. Also, as the check valve cover is mounted through the four mounting holes at the four corners with or without use of adhesives over the four edges of the cover, the installation/removal of the check valve cover is easy and beneficial for maintenance. In addition to these advantages, the present check valve provides advantage of vibration free/noiseless operation of cooling fans.

Thus, the present disclosure provides a check valve cover that can be installed on unique fans or on off-the-shelf standard size fans in market, and therefore, does not require designing and manufacturing to meet specific requirements of multi-fan assemblies. Further, the disclosed check valve cover is lightweight, easy to manufacture and install, provides reliable service, and therefore, provides a cost effective alternative to conventional check valves for cooling systems.

While the foregoing describes various implementations of the inventions hereof, other and further implementations of the inventions hereof may be devised without departing from the basic scope thereof. The scope of the inventions is determined by the claims that follow. The inventions are not limited to the described implementations, versions or examples, which are included to enable a person having ordinary skill in the art to make and use the inventions when combined with information and knowledge available to the person having ordinary skill in the art.

What is claimed is:

1. A check valve cover for blocking backflow of air through a non-operating fan, the check valve cover comprising:
a circumferential base for connection to a fan and
one or more flaps arranged in an annular pattern,
the one or more flaps each having
an outer substantially fixed portion and
an inner un-fixed portion;
the one or more flaps each being flexibly fixed at the outer fixed portion to the circumferential base and being freely movable at the inner un-fixed portion of the flap.

2. A check valve cover according to claim 1, wherein the one or more flaps are patterned on the check valve cover by slits with one side of each of the flaps remaining attached to the circumferential base.

3. A check valve cover according to claim 1, wherein, the one or more flaps have thin film cross section.

4. A check valve cover according to claim 1, wherein the cross section of the one or more flaps has tapering thickness being thicker at the outer substantially fixed portion and thinner at the inner un-fixed portion.

5. A check valve cover according to claim 1, wherein each of the flaps is of a generally of trapezoidal shape with unequal parallel sides, wherein larger of the two parallel sides forms the outer substantially fixed portion, and smaller of the two parallel sides form the inner un-fixed portion.

6. A check valve cover according to claim 5, wherein the smaller of the two parallel sides is curved not unlike the outer diameter of the hub of the fan.

7. A check valve cover according to claim 5, wherein the trapezoidal shaped flaps are positioned next to each other to define a regular or irregular convex polygon, wherein the larger of the two parallel sides of the trapezoidal shaped flaps define sides of the polygon, and the curved smaller of the two parallel sides define an aperture in the center not unlike the hub of the fan.

8. A check valve cover according to claim 1, wherein the flaps cover the annular space between outer diameter and the hub of the fan.

9. A check valve cover according to claim 1, wherein the one or more flaps have one or both of a self-closing or resilient property, wherein the one or more flaps open out under force of fan-forced exhaust airflow but close by themselves when the fan-forced exhaust airflow is stopped.

10. A check valve cover according to claim 1, wherein the check valve cover incorporates one or more transverse slots along one or more of the outer substantially fixed portion of each of the one or more flaps that keep the respective flaps attached to the circumferential base of the check valve cover.

11. A check valve cover according to claim 1, wherein the check valve cover incorporates one or more anti-vibration holes.

12. A check valve cover according to claim 11, wherein the one or more anti-vibration holes are located between adjacent flaps of the one or more flaps, and wherein the one or more anti-vibration holes allow passage of small amount of air through the check valve cover to prevent vibrations in the one or more flaps.

13. A check valve cover according to claim 5, wherein the check valve cover is configured for direct fitment on the output side of the fan and is of square shape matching shape of the fan; and wherein the polygon with an aperture in the center defined by the trapezoidal shaped flaps lies within the square shaped check valve cover.

14. A check valve cover according to claim 13, wherein the square shaped check valve cover further incorporates a depending skirt around periphery projecting toward the side facing the fan, wherein the skirt wraps around outer periphery of the fan.

15. A check valve cover according to claim 13, wherein the square shaped check valve cover further incorporates holes at the four corners, and wherein the holes match similar holes in the fan and facilitate fitment of the check valve cover on the fan.

16. A check valve cover according to claim 15, wherein the check valve cover further incorporates raised ribs on the outer face, wherein the raised ribs are positioned around the four holes and side edges of the check valve cover to strengthen the check valve cover.

17. A check valve cover according to claim 1, wherein the check valve cover is made of silicon rubber, and manufactured by molding process.

18. A method for preventing backflow of air through a nonoperational fan, the method comprising steps of:
providing a check valve cover on the outlet side of a fan, wherein the check valve cover comprises:
a circumferential base for connection to the fan and
one or more flaps arranged in an annular pattern, the one or more flaps each having an outer substantially fixed portion, and an inner un-fixed portion;
the one or more flaps each being flexibly fixed at the outer fixed portion to the circumferential base and being freely movable at the inner un-fixed portion of the flap;
preventing backflow by the one or more flaps blocking the flow of air into the fan when the corresponding fan is not in operation;
alternately opening the one or more flaps outwardly under influence of airflow being exhausted by the corresponding fan.

19. A method according to claim 18, wherein the one or more flaps have one or both of an auto-closing or a resilient property, wherein the one or more flaps open out under force of fan-forced exhaust airflow but close by themselves when the exhaust airflow is stopped.

20. A method according to claim 18, wherein an adequate space on outlet side of the check valve cover is provided by maintaining a suitable gap between the check valve cover and airflow outlet plate of the fan assembly.
